(19) United States
(12) Patent Application Publication
(10) Pub. No.: US 2018/0205366 A1
(43) Pub. Date: Jul. 19, 2018

(54) APPARATUS AND METHOD FOR PERFORMING A CONSISTENCY TESTING USING NON-LINEAR FILTERS THAT PROVIDE PREDICTIVE PROBABILITY DENSITY FUNCTIONS

(71) Applicant: Honeywell International Inc., Morris Plains, NJ (US)

(72) Inventors: Milos Vesely, Nemcice (CZ); Milos Sotak, Slavkov u Brna (CZ); Jindrich Dunik, Plzen (CZ)

(21) Appl. No.: 15/408,534

(22) Filed: Jan. 18, 2017

(51) Int. Cl. H03H 17/02; G06F 17/18

(52) U.S. Cl. CPC H03H 17/0261; H03H 17/0257; G06F 17/18

(57) ABSTRACT

A method is provided. The method comprises: initializing at least one non-linear filter configured to provide at least one predictive measurement estimate probability density function; obtaining measurement data; determining if the measurement data is consistent; and if the measurement data is consistent, then estimating at least one state parameter with the at least one non-linear filter using the measurement data.

### BACKGROUND

Extended Kalman filters are used to perform state estimation of non-linear systems. Most extended Kalman filters comprise a measurement model and a model of the non-linear system, of which states are estimated. The filters cyclically perform two steps: the prediction step and the filtering step.

In the prediction step, the model of the non-linear system is used to predict a future value of one or more states, or a predictive estimate of the states. In the filtering step, measurement data is used to correct the predictive estimate, and generates a filtered estimate of the states. The filtered estimate of the states is in the form of the first two moments of the state estimate.

The filtered estimate of the states is typically more accurate than the predictive estimate of the states because of the use of the measurement data. However, the measurement data can be inconsistent with the measurement model. For example, the measurement data may be erroneous due to noise or sensor degradation. Such inconsistent measurement data should not be used because it would corrupt the predictive estimate of the states.

Predicted measurement data can be generated with the extended Kalman filter. The measurement data can be compared to the predicted measurement data to determine if the measurement data is within an expected range of the predicted measurement data. If the measurement data is within the expected range of the predicted measurement data, the measurement data is deemed consistent, and then is used in the filtering step to compute the filtered estimate of the states. The use of only consistent measurement data ensures accurate and reliable state estimates and prevents filter divergence due to false measurements. However, use of extended Kalman filters is not always preferable.

### SUMMARY

A method is provided. The method comprises: initializing at least one non-linear filter configured to provide at least one predictive measurement estimate probability density function; obtaining measurement data; determining if the measurement data is consistent; and if the measurement data is consistent, then estimating at least one state parameter with the at least one non-linear filter using the measurement data.

### DRAWINGS

Understanding that the drawings depict only exemplary embodiments and are not therefore to be considered limiting in scope, the exemplary embodiments will be described with additional specificity and detail through the use of the accompanying drawings, in which:

FIG. 1 illustrates an exemplary block diagram of a system including at least one non-linear filter that provides predictive measurement probability density functions;

FIG. 2 illustrates an exemplary method of operation of a non-linear estimator that provides predictive measurement probability density function estimates;

FIG. 3 illustrates one embodiment of a method of determining if the measurement data is consistent;

FIG. 4 illustrates one embodiment of a scalar unimodal probability density function (PDF) having an allowed area and two forbidden areas;

FIG. 5 illustrates one embodiment of a scalar multi-modal PDF having two allowed areas and three forbidden areas.

In accordance with common practice, the various described features are not drawn to scale but are drawn to emphasize specific features relevant to the exemplary embodiments. Reference characters denote like elements throughout figures and text.

### DETAILED DESCRIPTION

In the following detailed description, reference is made to the accompanying drawings that form a part hereof, and in which is shown by way of illustration specific illustrative embodiments. However, it is to be understood that other embodiments may be utilized and that structural, mechanical, and electrical changes may be made. Furthermore, the method presented in the drawing figures and the specification is not to be construed as limiting the order in which the individual steps may be performed. The following detailed description is, therefore, not to be taken in a limiting sense.

Non-linear filters other than extended Kalman filters may be utilized to perform state estimation of non-linear systems. Some such non-linear filters provide a state estimate in the form of a probability density function (PDF) rather than in the form of the first two moments of the state estimate. Such non-linear filters include particle filters, Gaussian sum filters, point mass filters. Particle filters include Rao-Blackwellized particle filters. Point mass filters include Rao-Blackwellized point mass filters. These non-linear filters may be configured to provide both state estimates and predictive measurement probability density functions (PDFs). Techniques for performing consistency testing using non-linear filters configured to provide predictive measurement PDFs are subsequently described.

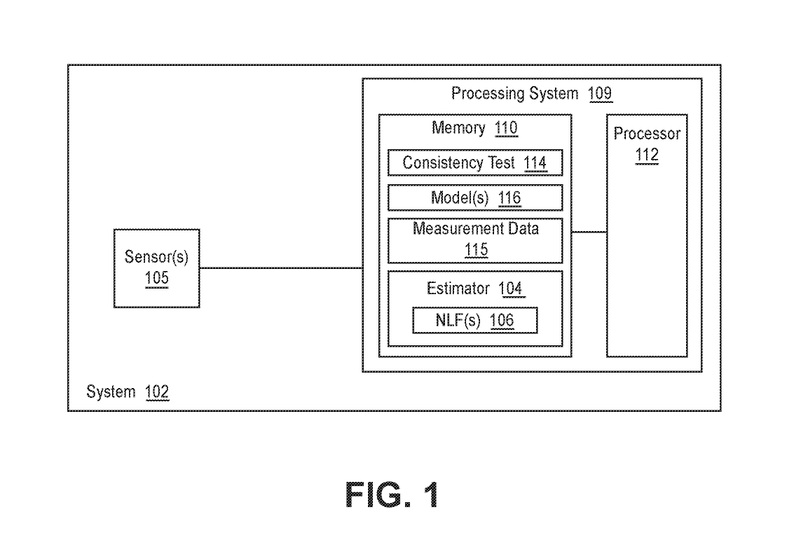

FIG. 1 illustrates an exemplary block diagram of a system including at least one non-linear filter configured to provide predictive measurement PDFs (System) 102. The system including at least one non-linear filter that provides predictive measurement PDFs 102 may also be referred to herein as a system including at least one non-linear filter 102.

In one embodiment, the system 102 comprises a processing system 109 coupled to an at least one sensor 105. The at least one sensor 105 measures data. In one example, the at least one sensor 105 may measure a quantity associated with a horizontal position on a known surface. In this embodiment, the one or more sensor 105 may include one or more of altimeters (e.g. barometric and/or radar), pressure sensors, accelerometers (e.g. measuring gravity), magnetometers, gravity gradiometers, gravimeters, water depth sensors, a bathymetric echo-sounder, a camera-type sensor, star trackers, and/or inertial measurement units including accelerometer(s) and/or gyroscope(s).

In one embodiment, the processing system 109 comprises a memory 110 coupled to a processor 112. In another embodiment, an estimator 104, a consistency test 114, measurement data 115, and at least one model 116 are stored in the memory 110. In a further embodiment, other data is stored in the memory 110. The measurement data 115 is data measured by the at least one sensor 105. The consistency test 114 and the at least one model 116 will be subsequently described. In one embodiment, the consistency test 114, the at least one model 116 and the estimator 104 may be stored in the form of executable software. In another embodiment, the processing system 109 may be a state machine. In a further embodiment, the processing system 109 may be a field programmable gate array.

The estimator 104 includes the at least one non-linear filter configured to provide at least one measurement predictive PDF (NLF(s)) 106. Non-linear filters configured to provide at least one measurement predictive PDF 106 can include one or more of particle filters, Gaussian sum filters, and point mass filters. Point mass filters include Rao-Blackwellized point mass filters. Particle filters include Rao-Blackwellized particle filters. The estimator 104 is also used to estimate state parameters of the at least one model 116, i.e. state-space models for a non-linear system. In one embodiment, the state parameters include the horizontal position on the surface, and which is estimated based upon the at least one model 116, the measurement data 115, and the estimator 104.

In one embodiment, the at least one model 116 include without limitation a state space model for direct and/or indirect estimation of the state parameter. The state space model describes time-evolution of state parameters, e.g., of the horizontal position of an object, and/or of the error (e.g. bias, noise, or correlated noise) of the at least one sensor 105. In another embodiment, the state space model comprises a state equation that is linear and a measurement equation that is non-linear. In a further embodiment, the at least one model 116 are a state space model comprising a state equation and a measurement equation. The measurement equation relates directly unmeasurable state parameters with available measurements of the at least one sensor 105. Definition of the state variables, selection of the sensor measurements, and design of the state-space model is specified by a filter designer.

The following is an exemplary state-space model describing a non-linear system. The state-space model is in a form of a state equation (for xₖ₊₁) and a measurement equation (for zₖ):

xₖ₊₁f(xₖ,uₖ,wₖ)

zₖ=h(xₖ)+vₖ (Equation 1)

where xₖ∈Rⁿ^{ₓ} is an unknown state, which is not directly measurable, at time instant k, uₖ∈Rⁿ^{ᵤ}; is a known input, zₖ∈Rⁿ^{_{z}} is a measurement parameter, wₖ∈Rⁿ^{_{w}} is a state noise with a known probability density function p_{w}(wₖ), vₖ∈Rⁿ^{ᵥ} is a measurement noise with a known probability density function pᵥ(vₖ), and f(⋅) and h(⋅) are known functions which possible vary over time. Based upon the measurement equation, the measurement PDF can be computed from the state-space model measurement equation:

p(zₖ|xₖⁿ)=pᵥ(zₖ−h(xₖ)) (Equation 2)

The predictive estimate of the state xₖ at time k, computed using the state-space model and all measurements up to the time instant k−1, is described by a conditional PDF:

p(xₖ|z^{k-1}) (Equation 3)

where zₖ₋₁=[z₁, . . . , zₖ₋₁] represents all measurements up to the time instant k−1. The conditional PDF is provided by the estimator 104.

Based upon the measurement PDF and the predictive state estimate PDF, the predictive PDF for measurement data 115, i.e., the measurement predictive PDF, is computed using the Chapman-Kolmogorov equation:

p(zₖ|z^{k-1})=∫p(zₖ,xₖ|z^{k-1})dxₖ=∫p(zₖ|xₖ)p(xₖ|z^{k-1})dxₖ (Equation 4)

where the at least one predictive measurement PDF p(zₖ|xₖ) is derived from the measurement equation.

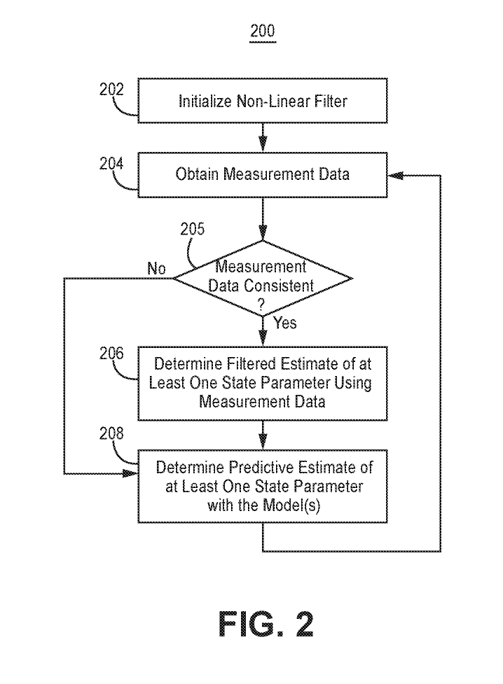

FIG. 2 illustrates an exemplary method 200 of operation of at least one non-linear filter configured to provide at least one measurement predictive PDF 106. To the extent that the embodiment of method 200 shown in FIG. 2 is described herein as being implemented in the system shown in FIG. 1, it is to be understood that other embodiments can be implemented in other ways. The blocks of the flow diagrams have been arranged in a generally sequential manner for ease of explanation; however, it is to be understood that this arrangement is merely exemplary, and it should be recognized that the processing associated with the methods (and the blocks shown in the Figures) can occur in a different order (for example, where at least some of the processing associated with the blocks is performed in parallel and/or in an event-driven manner).

In block 202, initialize at least one non-linear filter by storing an a priori estimate of a state parameter. In one embodiment, initialization is performed by providing at least one PDF with an a priori estimate of the state.

Thus, at least one predictive PDF p(xₖ|z^{k-1}) is determined, or computed. In one embodiment, the at least one non-linear estimator that provides at least one predictive PDF is at least one point mass filter (PMF). In this embodiment, the at least one predictive PDF is approximated by a point-mass density. The at least one predictive PDF can be determined, or computed, as follows:

$$p ( {x}_{k} \vert {z}^{k - 1} ) ≅ {\sum }_{i} {P}_{k \vert k - 1}^{( i )} ( {ξ}_{k}^{( i )} ) S \{ {x}_{k} \text{:} {ξ}_{k}^{( i )} , {Δ}_{x} \} \qquad ( Equation 5 )$$

Where ξₖ⁽ⁱ⁾∈Rⁿ^{ₓ} is an i-th grid point, i=1, 2, . . . , Nₓ, and P_{k|k-1}⁽ⁱ⁾(ξₖ⁽ⁱ⁾) is a respective value of the conditional PDF at the point, and S{xₖⁿ:ξₖ⁽ⁱ⁾, δ_{LonLat}} is a piece-wise constant (grid point selection) function of variable xₖⁿ at the point ξk⁽ⁱ⁾ being one at a vicinity Δₓ of the point ξₖ⁽ⁱ⁾ and zero otherwise. The vicinity Δₓ may or may not be the same for all grid points ξₖ⁽ⁱ⁾.

In block 204, obtain (or load) measurement data 115. In block 205, determine if the measurement data 115 is consistent. Consistent measurement data is measurement data 115 that is in an expected range (or allowed area) of the at least one measurement predictive PDF as specified as follows. The at least one predictive measurement PDF is divided into two regions:

an allowed area where the measurement zₖ is expected to be; and

a forbidden area where the measurement zₖ is not expected to be.

The allowed and forbidden areas are defined by a probability of false alert, e.g. specified by a designer of the at least one non-linear filter configured to provide at least one measurement predictive PDF (NLF(s)) 106, and a shape of the at least one predictive measurement PDF. The specific methods for determining the allowed and forbidden areas are exemplified below with regards to a point mass filter (PMF), although other non-linear filters that provide the at least one predictive measurement PDF can be used; examples of other non-linear filters are provided above.

In one embodiment, if such measurement data 115 is not consistent, then proceed to block 208. If the measurement data 115 is consistent, then proceed to block 206. In block 206, determine, or compute, the filtered estimate of at least one state parameter with the non-linear filter using the measurement data 115.

In block 208, determine, or compute, the predictive estimate of at least one state parameter and at least one predictive measurement PDF with the non-linear filter using the models 116. The predictive measurement PDF is a new a priori estimate of the measurement data 115 to be subsequently measured. In one embodiment, at least one predictive PDF is determined, or computed, as described above with respect to Equation 5. In another embodiment, return to block 204 and continue the process.

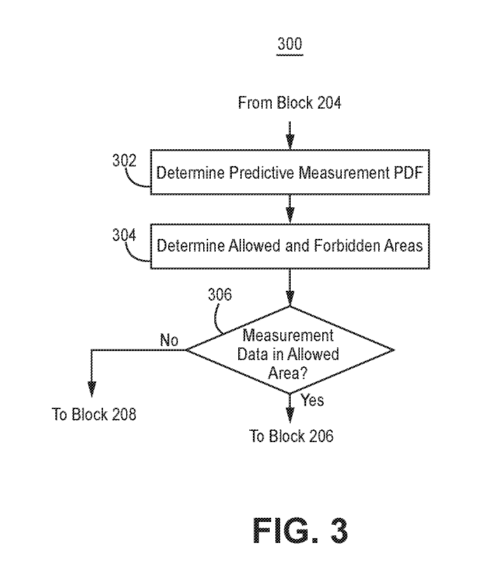

One embodiment of block 205 will now be described. FIG. 3 illustrates one embodiment 300 of a method of determining if the measurement data 115 is consistent. To the extent that the embodiment of method 300 shown in FIG. 3 is described here as being implemented in the system shown in FIG. 1, it is to be understood that other embodiments can be implemented in other ways. The blocks of the flow diagrams have been arranged in a generally sequential manner for ease of explanation; however, it is to be understood that this arrangement is merely exemplary, and it should be recognized that the processing associated with the methods (and the blocks shown in the Figures) can occur in a different order (for example, where at least some of the processing associated with the blocks is performed in parallel and/or in an event-driven manner).

In block 302, determine, or compute the at least one predictive measurement PDF. In one embodiment, obtain from the block 202 or 208 (whichever last preceded block 302) the at least one predictive PDF, and then determine, or calculate, the at least one predictive measurement PDF.

In one embodiment, the at least one predictive measurement PDF is determined using the Chapman-Kolmogorov equation illustrated in Equation 4. When the non-linear filter is a point mass filter, the at least one predictive PDF is approximated, using a convolution, by the point-mass approximation:

$$p ( {z}_{k} \vert {z}^{k - 1} ) ≅ {\sum }_{j} {P}_{k \vert k - 1}^{( j )} ( {α}_{k}^{( j )} ) S \{ {z}_{k} \text{:} {α}_{k}^{( j )} , {Δ}_{z} \} \qquad ( Equation 6 )$$

where the measurement grid is defined by the suitably selected equidistantly placed grid points spanning the expect range of the measurement:

α^{(j)}∈Rⁿ^{_{z}}, j=1,2, . . . ,N_{z} (Equation 7)

and the probability of the j-th measurement grid point α^{(j)} is computed on the basis of the measurement PDF and the probability of the i-th state grid point ξₖ⁽ⁱ⁾ by:

$${P}_{k \vert k - 1}^{( j )} ( {α}_{k}^{( j )} ) = {\sum }_{i = 1}^{{N}_{LonLat}} {p}_{v} ( {α}_{k}^{( j )} - h ( {ξ}_{k}^{( i )} ) ) {P}_{k \vert k - 1}^{( i )} ( {ξ}_{k}^{( i )} ) , \text{∀} j \qquad ( Equation 8 )$$

The measurement data 115 should be within this region. The respective vicinity of the grid points is defined by Δ_{z}. The vicinity Δ_{z} may or may not be the same for all grid points α⁽ⁱ⁾. The computation is performed in a manner analogous to computing the at least one predictive measurement PDF.

In block 304, determine the allowed and forbidden areas. The analysis for block 304 shall be exemplified for three embodiments.

For the first embodiment, the consistency test for the at least one measurement predictive PDF that is a unimodal PDF is described. For scalar unimodal PDFs, the consistency test is performed as follows. Based upon a probability of false alert P_{FA}, e.g. specified by the filter designer and a predictive measurement estimate PDF p(zₖ|z^{k-1}) for a scalar measurement, the following quantiles are computed:

quantile for P_{FA,q1}=P_{FA}/2, denoted \hat{z}_{q1,k|k-1}, and

quantile for P_{FA,q2}=1−P_{FA}/2, denoted \hat{z}_{q2,k|k-1}. (Equation 9)

Then, the allowed area is the range of possible measurement data between the quantiles:

\hat{z}_{q1,k|k-1}≤zₖ\hat{z}_{q2,k|k-1} (Equation 10)

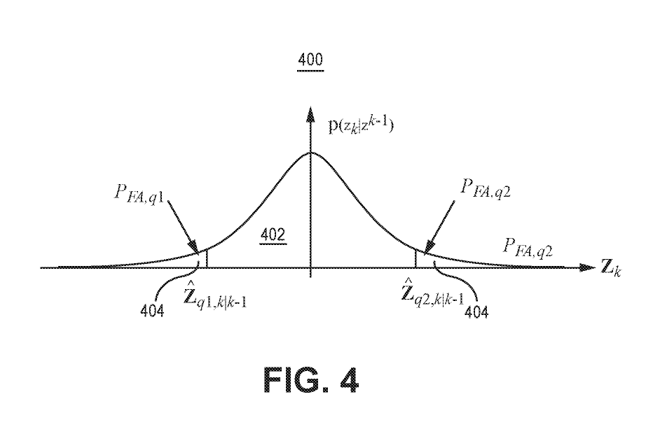

Measurement data 115 that falls within this range is deemed acceptable. If the measurement data 115 falls outside this range, i.e. in the forbidden area, the measurement data 115 is deemed faulty and is rejected. FIG. 4 illustrates one embodiment of a scalar unimodal PDF 400 having an allowed area 402 and two forbidden areas 404.

Consistency testing may also be performed for multi-dimensional unimodal predictive measurement PDFs. In one embodiment, if measurement is considered to be a vector, the consistency of each measurement vector component may be evaluated as described above. However, this approach ignores the correlation between the measurement vector components. Alternatively, the consistency of the vector measurement considering the unimodal predictive measurement PDF can be determined using a hyper-ellipsoid. The hyper-ellipsoid E is computed to fulfill the following equation:

$$1 - {P}_{FA} = {\int }_{E}^{ } p ( {z}_{k} \vert {z}^{k - 1} ) {dz}_{k} \qquad ( Equation 11 )$$

The allowed region would be a part of a support, which is defined by the hyper-ellipsoid.

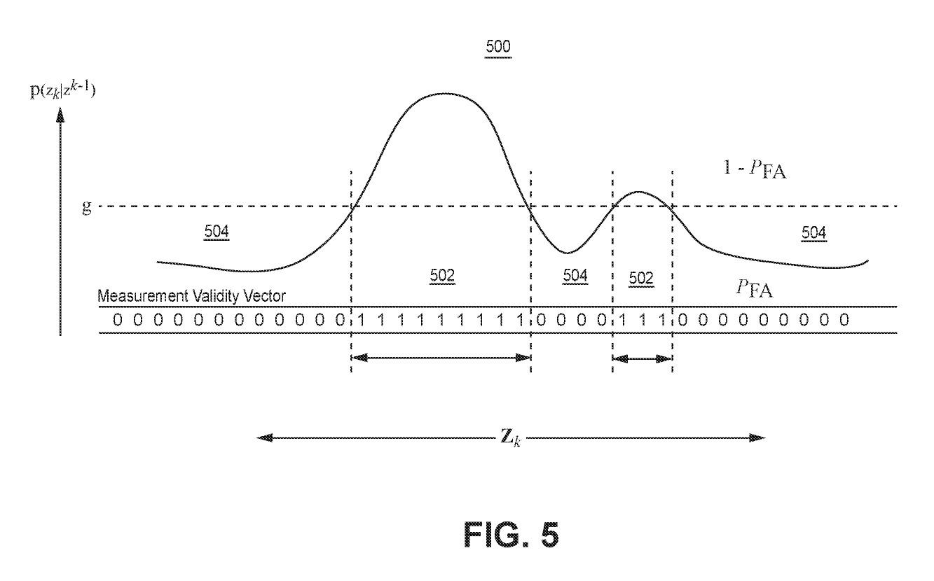

For the second embodiment, a consistency test for scalar multi-modal PDFs is described. FIG. 5 illustrates one embodiment of a scalar multi-modal PDF 500 having two allowed areas 502 and three forbidden areas 504.

A conditional PDF of the measurement zₖ at time k, equal to a probability value threshold g is determined, or calculated:

p(zₖ|z^{k-1})=g (Equation 12)

where volume of p(zₖ|z^{k-1}) below the threshold g is equal to the probability of false alert P_{FA}, and volume of p(zₖ|z^{k-1}) above the threshold g is equal to 1−P_{FA}. In one embodiment, the probability of false alert is specified by a designer of the at least one non-linear filter.

Implemented with a PMF, the probability value threshold g is determined as follows:

Probability Value Threshold g

$$so that {\sum }_{j = 1}^{{N}_{z , g}} {P}_{k \vert k - 1}^{( j )} ( {α}_{k}^{( j )} ) {Δ}_{z} = 1 - {P}_{FA} \qquad ( Equation 13 )$$

where:
N_{z,g}=indexes of points for which: P_{k|k-1}^{(j)}(αₖ^{(j)})Δ_{z}≥g

Measurement Validity Vector υ_{α}

$${v}_{α} = \{ \begin{matrix}{v}_{α ( j )} = 1 & if {P}_{k \vert k - 1}^{( j )} ( {α}_{k}^{( j )} ) {Δ}_{z} \geq g \\ {v}_{α ( j )} = 0 & if {P}_{k \vert k - 1}^{( j )} ( {α}_{k}^{( j )} ) {Δ}_{z} < g\end{matrix} \qquad ( Equation 14 )$$

The measurement validity vector υₐ defines which areas determined by the expected measurement range αₖ^{(j)} and the vicinity Δ_{z} are allowed areas 502 (where υ_{α(j)}=1), and thus likely to contain the measurement data 115 for the measurement zₖ; and are forbidden areas 504 (where υ_{α(j)}=0), and thus not likely to contain the measurement data 115 for the measurement zₖ. The regions where P_{k|k-1}^{(j)}(αₖ^{(j)})Δ_{z}≥g are the allowed areas 502. The regions where P_{k|k-1}^{(j)}(αₖ^{(j)})Δ_{z}<g are the forbidden areas 504.

The measurement data 115 for measurement zₖ is considered consistent with measurement prediction if the measurement data 115 falls within any of the allowed areas 502, and inconsistent if it falls within any of the forbidden areas 504. This means that distance between measurement zₖ and the closest valid grid point is lower or equal to half of grid resolution:

$$\vert {z}_{k} - {α}_{k}^{( {N}_{z , g} )} \vert \leq \frac{{Δ}_{z}}{2} .$$

Then, the measurement data 115 for the measurement zₖ is used by the non-linear filter. Otherwise, the measurement data 115 for the measurement zₖ is rejected and not further used by the non-linear filter to estimate state parameters.

In one embodiment, for multi-dimensional multi-modal predictive measurement PDFs, the predictive state estimate and the at least one predictive measurement PDF are determined as described above. In one embodiment, n_{z}, marginal predictive measurement PDFs for each component of the measurement vector, are determined. Then, the consistency of each measurement vector component is evaluated as described above. Alternatively, the consistency of the multi-dimensional unimodal PDF can be determined using hyper-planes in n_{z} dimensional space so that the allowed areas are above the hyper-plane. The hyper-plane with an orthogonal distance g from the support of the predictive measurement PDF is computed to fulfill the equality:

1−P_{FA}=∫s(p(zₖ|z^{k-1}),g)p(zₖ|z^{k-1})dzₖ (Equation 15)

where s(p(zₖ|z^{k-1}),g) is a selection function being 1 if p(zₖ|z^{k-1})>g and 0 otherwise.

For the third embodiment, a consistency test can be performed on unimodal or multi-modal scalar or multi-dimensional at least one predictive measurement PDF using approximation. The mean and covariance matrix of the at least one predictive measurement PDF p(zₖ|z^{k-1}) are determined. Assuming a Gaussian distribution of the at least one predictive measurement PDF with the mean and covariance matrix, the quantiles of the approximate Gaussian at least one predictive measurement estimate PDF for the probability of false alert P_{FA} are straightforwardly determined, and, e.g. stored or defined in at least one look up table, e.g. specifying a range of zₖ that defines allowable area(s) for a given P_{FA}. In one embodiment, the at least one look up table is part of the consistency test 114. Consistency can be determined if the measurement data 115 falls within the allowable area(s) that are between \hat{z}_{q1,k|k-1}≤zₖ \hat{z}_{q2,k|k-1}, where \hat{z}_{q1,k|k-1} is a Gaussian PDF quantile with P_{FA}/2 and \hat{z}_{q2,k|k-1} is a Gaussian PDF quantile with 1−P_{FA}/2.

When utilizing a point mass filter, the mean and covariance matrices of the at least one predictive measurement PDF are respectively determined as follows:

$$\begin{matrix} Mean Matrix \text{:} {\hat{z}}_{k \vert k - 1} = {\sum }_{j} {α}_{k}^{( j )} {P}_{k \vert k - 1}^{( j )} ( {α}_{k}^{( j )} ) {Δ}_{z} & ( Equation 15 ) \\ Covariance Matrix \text{:} {P}_{z , k \vert k - 1} = {\sum }_{j} {P}_{k \vert k - 1}^{( j )} ( {α}_{k}^{( j )} ) {Δ}_{z} ( {α}_{k}^{( j )} - {\hat{z}}_{k \vert k - 1} ) {( {α}_{k}^{( j )} - {\hat{z}}_{k \vert k - 1} )}^{T} & ( Equation 16 )\end{matrix}$$

A Gaussian distribution of the PDF p(zₖ|z^{k-1}) is assumed. As a result, the above described look up table(s) can be created based upon these two moments. Consistency can be determined if the measurement falls within the allowable area(s). Determining whether the at least one predictive measurement PDF is close to a Gaussian PDF (i.e., the assumption used in the third embodiment holds) can be performed by evaluating the moments of the PDF, like those described in Equation 16.

Returning to FIG. 3, in block 306, determine if the measurement data 115 is in an allowed area. In one embodiment, if the measurement data 115 for measurement zₖ is in an allowed area, then proceed to block 206. The measurement data 115 for measurement zₖ is deemed consistent with the at least one predictive measurement PDF, and is used by the at least one non-linear filter 106 to determine, or compute, a filtered estimate of at least one state parameter. In another embodiment, if the measurement data 115 for measurement zₖ is in the forbidden area, then proceed to block 208. The measurement data 115 for measurement zₖ is deemed inconsistent, e.g. rejected, and the computation of the filtered estimate of the at least one state parameter is skipped and a predictive state estimate is computed.

Although specific embodiments have been illustrated and described herein, it will be appreciated by those of ordinary skill in the art that any arrangement, which is calculated to achieve the same purpose, may be substituted for the specific embodiments shown. Therefore, it is manifestly intended that this invention be limited only by the claims and the equivalents thereof.

### Example Embodiments

Example 1 includes a system, comprising: at least one sensor; a processing system comprising a memory coupled to a processor; wherein the processing system is configured to be coupled to the at least one sensor; wherein the memory comprises a consistency test, at least one model, measurement data, and an estimator; wherein the measurement data comprises data measured by the at least one sensor; wherein the estimator comprises at least one non-linear filter which is configured to provide at least one predictive measurement probability density function (PDF); and wherein the estimator is configured to generate the at least one predictive measurement estimate PDF, and the consistency test is configured to determine if the measurement data is within at least one allowable area of the at least one predictive measurement estimate PDF.

Example 2 include the system of Example 1, wherein the at least one non-linear filter comprises at least one of a point mass filter, a particle filter, and a Gaussian sum filter.

Example 3 includes the system of any of Examples 1-2, wherein the at least one allowable area comprises: \hat{z}_{q1,k|k-1}≤zₖ≤\hat{z}_{q2,k|k-1}; where \hat{z}_{q1,k|k-1} is a quantile, of the at least one predictive measurement PDF, for P_{FA}/2; \hat{z}_{q2,k|k-1} is a quantile, of the at least one predictive measurement PDF, for 1−P_{FA}/2; and P_{FA} is a probability of a false alert.

Example 4 includes the system of any of Examples 3, wherein P_{FA} is by a designer of the estimator.

Example 5 includes the system of any of Examples 1-4, wherein the at least one allowable area comprises at least one volume of p(zₖ|z^{k-1}) above p(zₖ|z^{k-1})=g equals 1−P_{FA}; and wherein P_{FA} is a probability of a false alert.

Example 6 includes the system of Example 5, wherein P_{FA} is at least one of: specified by a designer of the estimator and based upon the at least one predictive measurement estimate PDF.

Example 7 includes the system of any of Examples 5-6, wherein the at least one allowable area comprises P_{k|k-1}^{(j)}(αₖ^{(j)})Δ_{z}≥g.

Example 8 includes the system of any of Examples 1-7, where the at least one allowable area is defined in a lookup table.

Example 9 includes the system of any of Examples 1-8, wherein if the measurement data determined to be within at least one allowable area, the estimator estimates at least one state parameter using measurement data.

Example 10 includes a method, comprising: initializing at least one non-linear filter configured to provide at least one predictive measurement estimate probability density function (PDF); obtaining measurement data; determining if the measurement data is consistent; and if the measurement data is consistent, then determining a filtered estimate of at least one state parameter with the at least one non-linear filter using the measurement data.

Example 11 includes the method of Example 10, further comprising determining a predictive estimate, with the at least one non-linear filter, of at least one state parameter using the measurement data.

Example 12 includes the method of any of Examples 10-11, wherein determining if the measurement data is consistent comprises: determining at least one predictive measurement PDF; determining at least one allowed area and at least one forbidden area in the at least one predictive measurement PDF; and determining if the measurement data is within the at least one allowed area of the at least one predictive measurement estimate PDF.

Example 13 includes the method of Example 12, wherein determining the at least one predictive measurement PDF comprises determining p(zₖ|z^{k-1})=∫p(zₖ,xₖ|z^{k-1})dxₖ=∫p(zₖ|xₖ)p(xₖ|z^{k-1})dxₖ; and wherein the at least one predictive measurement PDF p(zₖ|xₖ) is derived from a measurement equation.

Example 14 includes the method of any of Examples 12-13, wherein determining if the measurement data is within the at least one allowable area of the at least one predictive measurement estimate PDF comprises determining if the measurement data is within one allowable area of the at least one predictive measurement estimate PDF specified by: \hat{z}_{q1,k|k-1}≤zₖ\hat{z}_{q2,k|k-1}; where \hat{z}_{q1,k|k-1} is a quantile, of the predictive measurement PDF, for is P_{FA}/2; \hat{z}_{q2,k|k-1} is a quantile, of the predictive measurement PDF, for is 1−P_{FA}/2; and P_{FA} is a probability of a false alert.

Example 15 includes the method of any of Examples 12-14, wherein determining if the measurement data is within the at least one allowable area of the at least one predictive measurement estimate PDF comprises determining if the measurement data is within the at least one allowable area, of the at least one predictive measurement estimate PDF, that is at least one volume of p(zₖ|z^{k-1}) above p(zₖ|z^{k-1})=g equals 1−P_{FA}; and wherein P_{FA} is a probability of a false alert.

Example 16 includes the method of Example 15, wherein determining if the measurement data is within the at least one allowable area, of the at least one predictive measurement estimate PDF, that is at least one volume of p(zₖ|z^{k-1}) above p(zₖ|z^{k-1})=g equals 1−P_{FA}; and wherein P_{FA} is a probability of a false alert comprises determining if the measurement data is within the at least one allowable area of the at least one predictive measurement PDF that comprises P_{k|k-1}^{(j)}(αₖ^{(j)})Δ_{z}≥g.

Example 17 includes the method of any of Examples 12-16, determining if the measurement data is within the at least one allowable area of the at least one predictive measurement estimate PDF comprises determining if the measurement data is within the at least one allowable area, of the at least one predictive measurement estimate PDF, is defined in a lookup table.

Example 18 includes the method of any of Examples 10-17, wherein initializing the at least one non-linear filter configured to provide at least one predictive measurement estimate PDF wherein the at least one non-linear filter comprises initializing the at least one non-linear filter comprising at least one of a point mass filter, a particle filter, and a Gaussian sum filter.

Example 19 includes a method, comprising: initializing at least one non-linear filter configured to provide at least one predictive measurement estimate probability density function (PDF); obtaining measurement data; determining at least one predictive measurement PDF; determining at least one allowed area and at least one forbidden area in the at least one predictive measurement PDF; determining if the measurement data is within at least one allowable area of the at least one predictive measurement estimate PDF specified by: \hat{z}_{q1,k|k-1}≤zₖ≤\hat{z}_{q2,k|k-1}; where \hat{z}_{q1,k|k-1} is a quantile, of the predictive measurement PDF, for P_{FA}/2; \hat{z}_{q2,k|k-1} is a quantile, of the predictive measurement PDF, for 1−P_{FA}/2; and P_{FA} is a probability of a false alert; and if the measurement data is consistent, then estimating at least one state parameter with the at least one non-linear filter using the measurement data.

Example 20 includes the method of Example 19, wherein determining the at least one predictive measurement PDF comprises determining p(zₖ|z^{k-1})=∫p(zₖ,xₖ|z^{k-1})dxₖ=∫p(zₖ|xₖ)p(xₖ|z^{k-1})dxₖ; and where the at least one predictive measurement PDF p(zₖ|xₖ) is derived from a measurement equation.

Although specific embodiments have been illustrated and described herein, it will be appreciated by those of ordinary skill in the art that any arrangement, which is calculated to achieve the same purpose, may be substituted for the specific embodiments shown. Therefore, it is manifestly intended that this invention be limited only by the claims and the equivalents thereof.

What is claimed is:

1. A system, comprising:
at least one sensor;
a processing system comprising a memory coupled to a processor;
wherein the processing system is configured to be coupled to the at least one sensor;
wherein the memory comprises a consistency test, at least one model, measurement data, and an estimator;
wherein the measurement data comprises data measured by the at least one sensor;
wherein the estimator comprises at least one non-linear filter which is configured to provide at least one predictive measurement probability density function (PDF); and
wherein the estimator is configured to generate the at least one predictive measurement estimate PDF, and the consistency test is configured to determine if the measurement data is within at least one allowable area of the at least one predictive measurement estimate PDF.

2. The system of claim 1, wherein the at least one non-linear filter comprises at least one of a point mass filter, a particle filter, and a Gaussian sum filter.

3. The system of claim 1, wherein the at least one allowable area comprises:
\hat{z}_{q1,k|k-1}≤zₖ≤\hat{z}_{q2,k|k-1};
where \hat{z}_{q1,k|k-1} is a quantile, of the at least one predictive measurement PDF, for P_{FA}/2;
\hat{z}_{q2,k|k-1} is a quantile, of the at least one predictive measurement PDF, for 1−P_{FA}/2; and
P_{FA} is a probability of a false alert.

4. The system of claim 3, wherein P_{FA} is by a designer of the estimator.

5. The system of claim 1, wherein the at least one allowable area comprises at least one volume of p(zₖ|z^{k-1}) above p(zₖ|z^{k-1})=g equals 1−P_{FA}; and
wherein P_{FA} is a probability of a false alert.

6. The system of claim 5, wherein P_{FA} is at least one of: specified by a designer of the estimator and based upon the at least one predictive measurement estimate PDF.

7. The system of claim 5, wherein the at least one allowable area comprises P_{k|k-1}^{(j)}(αₖ^{(j)})Δ_{z}≥g.

8. The system of claim 1, where the at least one allowable area is defined in a lookup table.

9. The system of claim 1, wherein if the measurement data determined to be within at least one allowable area, the estimator estimates at least one state parameter using measurement data.

10. A method, comprising:
initializing at least one non-linear filter configured to provide at least one predictive measurement estimate probability density function (PDF);
obtaining measurement data;
determining if the measurement data is consistent; and
if the measurement data is consistent, then determining a filtered estimate of at least one state parameter with the at least one non-linear filter using the measurement data.

11. The method of claim 10, further comprising determining a predictive estimate, with the at least one non-linear filter, of at least one state parameter using the measurement data.

12. The method of claim 10, wherein determining if the measurement data is consistent comprises:
determining at least one predictive measurement PDF;
determining at least one allowed area and at least one forbidden area in the at least one predictive measurement PDF; and
determining if the measurement data is within the at least one allowed area of the at least one predictive measurement estimate PDF.

13. The method of claim 12, wherein determining the at least one predictive measurement PDF comprises determining
p(zₖ|z^{k-1})=∫p(zₖ,xₖ|z^{k-1})dxₖ=∫p(zₖ|xₖ)p(xₖ|z^{k-1})dxₖ; and
wherein the at least one predictive measurement PDF p(zₖ|xₖ) is derived from a measurement equation.

14. The method of claim 12, wherein determining if the measurement data is within the at least one allowable area of the at least one predictive measurement estimate PDF comprises determining if the measurement data is within one allowable area of the at least one predictive measurement estimate PDF specified by:
\hat{z}_{q1,k|k-1}≤zₖ≤\hat{z}_{q2,k|k-1};
where \hat{z}_{q1,k|k-1} is a quantile, of the predictive measurement PDF, for is P_{FA}/2;
\hat{z}_{q2,k|k-1} is a quantile, of the predictive measurement PDF, for is 1−P_{FA}/2; and
P_{FA} is a probability of a false alert.

15. The method of claim 12, wherein determining if the measurement data is within the at least one allowable area of the at least one predictive measurement estimate PDF comprises determining if the measurement data is within the at least one allowable area, of the at least one predictive measurement estimate PDF, that is at least one volume of p(zₖ|z^{k-1}) above p(zₖ|z^{k-1})=g equals 1−P_{FA}; and
wherein P_{FA} is a probability of a false alert.

16. The method of claim 15, wherein determining if the measurement data is within the at least one allowable area, of the at least one predictive measurement estimate PDF, that is at least one volume of p(zₖ|z^{k-1}) above p(zₖ|z^{k-1})=g equals 1−P_{FA}; and wherein P is a probability of a false alert comprises determining if the measurement data is within the at least one allowable area of the at least one predictive measurement PDF that comprises P_{k|k-1}^{(j)}(αₖ^{(j)})Δ_{z}≥g.

17. The method of claim 12, determining if the measurement data is within the at least one allowable area of the at least one predictive measurement estimate PDF comprises determining if the measurement data is within the at least one allowable area, of the at least one predictive measurement estimate PDF, is defined in a lookup table.

18. The method of claim 10, wherein initializing the at least one non-linear filter configured to provide at least one predictive measurement estimate PDF wherein the at least one non-linear filter comprises initializing the at least one non-linear filter comprising at least one of a point mass filter, a particle filter, and a Gaussian sum filter.

19. A method, comprising:
initializing at least one non-linear filter configured to provide at least one predictive measurement estimate probability density function (PDF);
obtaining measurement data;
determining at least one predictive measurement PDF;
determining at least one allowed area and at least one forbidden area in the at least one predictive measurement PDF;
determining if the measurement data is within at least one allowable area of the at least one predictive measurement estimate PDF specified by:
\hat{z}_{q1,k|k-1}≤zₖ≤\hat{z}_{q2,k|k-1};
where \hat{z}_{q1,k|k-1} is a quantile, of the predictive measurement PDF, for P_{FA}/2;
\hat{z}_{q2,k|k-1} is a quantile, of the predictive measurement PDF, for 1−P_{FA}/2; and
P_{FA} is a probability of a false alert; and
if the measurement data is consistent, then estimating at least one state parameter with the at least one non-linear filter using the measurement data.

20. The method of claim 19, wherein determining the at least one predictive measurement PDF comprises determining
p(zₖ|z^{k-1})=∫p(zₖ,xₖ|z^{k-1})dxₖ=∫p(zₖ|xₖ)p(xₖ|z^{k-1})dxₖ; and
where the at least one predictive measurement PDF p(zₖ|xₖ) is derived from a measurement equation.
